(19) United States
(12) Patent Application Publication
(10) Pub. No.: US 2025/0220809 A1
(43) Pub. Date: Jul. 3, 2025

(54) STACKED STRUCTURE, ELECTRONIC DEVICE, AND METHOD OF FABRICATING THE STACKED STRUCTURE

(71) Applicant: Samsung Electronics Co., Ltd., Suwon-si (KR)

(72) Inventors: Vanluan NGUYEN, Suwon-si (KR); Jaewon KIM, Suwon-si (KR); Taehoon KIM, Suwon-si (KR); Hyeonjin SHIN, Suwon-si (KR); Taejin CHOI, Suwon-si (KR)

(73) Assignee: Samsung Electronics Co., Ltd., Suwon-si (KR)

(21) Appl. No.: 18/758,455

(22) Filed: Jun. 28, 2024

(30) Foreign Application Priority Data
Dec. 29, 2023 (KR) 10-2023-0197700

(51) Int. Cl. H05K 1/02; H05K 3/22

(52) U.S. Cl. CPC H05K 1/0296; H05K 3/22

(57) ABSTRACT

A stacked structure includes a plurality of amorphous material layers each having a first dielectric constant and a first thickness, and an intermediate layer disposed between the plurality of amorphous material layers and having a second dielectric constant and a second thickness less than the first thickness, wherein the first dielectric constant may be 2.5 or less, a difference between the first dielectric constant and the second dielectric constant may be less than or equal to twice the first dielectric constant, and an overall dielectric constant of the stacked structure may be 2.5 or less.

### CROSS-REFERENCE TO RELATED APPLICATION

This application is based on and claims priority under 35 U.S.C. § 119 to Korean Patent Application No. 10-2023-0197700, filed on Dec. 29, 2023, in the Korean Intellectual Property Office, the disclosure of which is incorporated by reference herein in its entirety.

### BACKGROUND

### 1. Field

The disclosure relates to a stacked structure, an electronic device, and a method of fabricating the stacked structure.

### 2. Description of the Related Art

Integrated circuits used in various electronic devices such as display devices, image sensors, field effect transistors, and memory elements may be manufactured by combining and connecting semiconductors, conductors, and insulators with each other. For example, integrated circuits used in various electronic devices may be manufactured by forming a plurality of unit elements on a substrate and then stacking an interlayer insulating layer and wiring on the plurality of unit elements.

As the degree of integration of integrated circuits has been markedly increased, the spacing between conductor patterns has been gradually decreased. As a result, the parasitic capacitance between conductor patterns increases, which may cause a decrease in the performance of electronic devices. For example, the parasitic capacitance may delay signal transmission in semiconductor devices. To reduce this parasitic capacitance, insulating materials having a relatively low dielectric constant have been proposed for fabricating interlayer insulating layers.

### SUMMARY

Provided are a stacked structure configured to maintain the dielectric constant of the stacked structure at a low level in spite of an increase in the thickness of the stacked structure, an electronic device, and a method of fabricating the stacked structure.

Additional aspects will be set forth in part in the description which follows and, in part, will be apparent from the description, or may be learned by practice of the presented embodiments of the disclosure.

According to an aspect of the disclosure, a stacked structure includes: a plurality of amorphous material layers each having a first thickness and a first dielectric constant of 2.5 or less; and an intermediate layer between each of the plurality of amorphous material layers and having a second dielectric constant and a second thickness less than the first thickness, wherein a difference between the first dielectric constant and the second dielectric constant is less than or equal to twice the first dielectric constant, and an overall dielectric constant of the stacked structure is 2.5 or less.

Each of the plurality of amorphous material layers may include an amorphous material including at least one of carbon (C), silicon (Si), boron (B), nitrogen (N), or oxygen (O).

Each of the plurality of amorphous material layers may include amorphous boron nitride, and the first dielectric constant may be 2.3 or less.

The intermediate layer may include a two-dimensional thin-film layer including a two-dimensional material.

The two-dimensional material may include at least one of a transition metal dichalcogenide, graphene, black phosphorus, or two-dimensional hexagonal boron nitride (h-BN).

The second thickness may be 1 nm (nanometer) or less.

The second thickness may be 20% or less of the first thickness.

A difference between the overall dielectric constant and the first dielectric constant may be within 10% of the first dielectric constant.

A number of the plurality of amorphous material layers may be five or more.

An overall thickness of the stacked structure may be 50 nm or more.

According to another aspect of the disclosure, an electronic device includes a substrate and a wiring structure on the substrate, wherein the wiring structure includes conductive wiring and a dielectric layer surrounding at least a portion of the conductive wiring, wherein the dielectric layer includes the stacked structure.

According to another aspect of the disclosure, a method of fabricating a stacked structure includes forming a first amorphous material layer on a substrate such that the first amorphous material layer has a first thickness and a first dielectric constant of 2.5 or less; forming an intermediate layer on the first amorphous material layer such that the intermediate layer has a second dielectric constant and a second thickness less than the first thickness; and forming a second amorphous material layer on the intermediate layer such that the second amorphous material layer has a third thickness greater than the second thickness and a third dielectric constant of 2.5 or less, wherein a difference between the first dielectric constant and the second dielectric constant is less than or equal to twice the first dielectric constant and a difference between the third dielectric constant and the second dielectric constant is less than or equal to twice the third dielectric constant, and wherein an overall dielectric constant of the stacked structure is 2.5 or less.

Each of the first and second amorphous material layers may be formed to include an amorphous material including at least one of carbon (C), silicon (Si), boron (B), nitrogen (N), and oxygen (O).

Each of the first and second amorphous material layers may be formed to include amorphous boron nitride.

The intermediate layer may be formed to include a two-dimensional thin-film layer including a two-dimensional material.

The two-dimensional material may include at least one of a transition metal dichalcogenide, graphene, black phosphorus, or two-dimensional hexagonal boron nitride (h-BN).

The intermediate layer may be formed to such that the second thickness of the intermediate layer may be 1 nm or less.

The intermediate layer may be formed to such that the second thickness of the intermediate layer may be 20% or less of the first thickness of each of the first and second amorphous material layers.

The forming of the intermediate layer and the forming of the second amorphous material layer may be alternately repeated such that the stacked structure includes a plurality of the intermediate layer between a plurality of the second amorphous material layer.

A total number of the first and second amorphous material layers may be five or more, and an overall thickness of the stacked structure may be 50 nm or more.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view schematically illustrating a stacked structure according to at least one embodiment;

FIG. 2 is a view illustrating a structure including a single layer of an amorphous material formed on a substrate;

FIG. 3 is a view schematically illustrating a stacked structure according to at least one embodiment;

FIGS. 4A to 4C are images obtained using a scanning electron microscope (SEM) to show cross-sections of structures or stacked structures of Example 1 and Comparative Examples 1 and 2;

FIG. 5 is a graph illustrating a relationship between a dielectric constant and a thickness in Example 1 and Comparative Examples 1 and 2;

FIG. 6 is a graph illustrating a relationship between a dielectric constant and a thickness of each of the structures of Example 2 and Comparative Example 3;

FIG. 7 is a cross-sectional view schematically illustrating a configuration of an electronic device including a wiring structure according to at least one embodiment; and

FIG. 8 is a schematic of an electronic device according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a stacked structure, an electronic device, and a method of fabricating the stacked structure will be described according to various embodiments with reference to the accompanying drawings. In the drawings, like reference numbers refer to like elements, and the size of each element may be exaggerated for clarity of illustration. It will be understood that although terms such as “first” and “second” may be used herein to describe various components, these components should not be limited by these terms. These terms are only used to distinguish one element from another.

As used herein, singular forms may include plural forms as well unless the context clearly indicates otherwise. It will be further understood that the terms “comprises,” “comprising,” “includes,” and/or “including” used herein specify the presence of stated features or elements, but do not preclude the presence or addition of one or more other features or elements. In the drawings, the size or thickness of each element may be exaggerated for clarity of illustration. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

Furthermore, it will be understood that when a material layer is referred to as being “on” or “above” a substrate or another layer, it can be directly on the substrate or the other layer, or intervening layers may also be present. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. Furthermore, in the following embodiments, a material included in each layer is an example, and another material may be used in addition to or instead of the material.

In the disclosure, terms such as “unit” or “module” may be used to denote a unit that has at least one function or operation and is implemented with processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Specific executions described herein are merely examples and do not limit the scope of the disclosure in any way. For simplicity of description, other functional aspects of conventional electronic configurations, control systems, software and the systems may be omitted. Furthermore, line connections or connection members between elements depicted in the drawings represent functional connections and/or physical or circuit connections by way of example, and in actual applications, they may be replaced or embodied as various additional functional connections, physical connections or circuit connections.

An element referred to with the definite article or a demonstrative pronoun may be construed as the element or the elements even though it has a singular form.

Operations of a method may be performed in appropriate order unless explicitly described in terms of order or described to the contrary. In addition, examples or exemplary terms (for example, “such as” and “etc.”) are used for the purpose of description and are not intended to limit the scope of the disclosure unless defined by the claims.

According to an aspect, in a stacked structure, an intermediate layer having low interfacial reactivity with amorphous material layers may be disposed between the amorphous material layers.

Layers known in the related art as low-dielectric material layers such as a boron nitride layer have limited applications because crystallization causing an increase in dielectric constant such as hexagonal crystal formation occurs in the layers as the deposition thicknesses of the layers increase.

However, according to an aspect, a stacked structure is provided by disposing an intermediate layer having low interfacial reactivity and a low dielectric constant between amorphous material layers each having a thickness within a range in which crystallization does not occur, and thus, the overall dielectric constant of the stacked structure may be similar to the dielectric constant of the amorphous material layers. Therefore, according to the aspect, although the thickness of the stacked structure increases, crystallization does not occur in the amorphous material layers, and thus, the dielectric constant of the stacked structure may remain at a low level. Therefore, the stacked structure may be applied to wiring structures required to have a low dielectric constant and various electronic devices including the wiring structures.

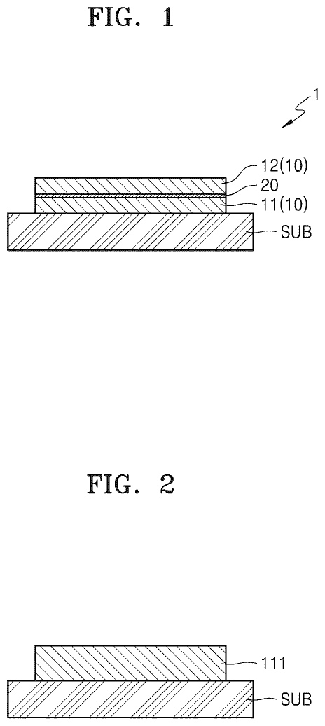

FIG. 1 is a view illustrating a stacked structure 1 according to at least one embodiment, and FIG. 2 is a view illustrating a comparative structure including a single-layer amorphous material layer 111 formed on a substrate SUB.

Referring to FIG. 1, according to at least one embodiment, the stacked structure 1 may include a plurality of amorphous material layers 10 and an intermediate layer 20 disposed between the amorphous material layers 10. For example, the stacked structure 1 may include a first amorphous material layer 11 disposed on a substrate SUB, an intermediate layer 20 disposed on the first amorphous material layer 11, and a second amorphous material layer 12 disposed on the intermediate layer 20.

Each of the amorphous material layers 10 may have a low dielectric constant. For example, the amorphous material layers 10 may be in an amorphous state and may each have a first dielectric constant. For example, the first dielectric constant may be 4.0 or less. For example, the first dielectric constant may be 3.5 or less. For example, the first dielectric constant may be 2.5 or less. The first dielectric constant may be 2.3 or less. For example, the first dielectric constant may range from about 1.0 to about 4.0. For example, the first dielectric constant may range from about 1.0 to about 3.0. For example, the first dielectric constant may range from about 1.5 to about 2.5. For example, the first dielectric constant may range from about 1.5 to about 2.3.

The amorphous material layers 10 may include at least one selected from carbon (C), silicon (Si), boron (B), nitrogen (N), and/or oxygen (O). For example, the amorphous material layers 10 may include amorphous boron nitride. For example, the amorphous material layers 10 may each be an amorphous boron nitride layer.

The amorphous material layers 10 may be disposed on the substrate SUB. In other words, among the amorphous material layers 10, a lowermost amorphous material layer 10 may be disposed on the substrate SUB.

The amorphous material layers 10 may be grown on the substrate SUB. For example, amorphous boron nitride layers may be grown on the substrate SUB. For example, in a state in which the substrate SUB is placed in a chamber, a reaction gas for growing lowermost amorphous material layer 11 including amorphous boron nitride may be injected into the chamber. The reaction gas may contain one or more precursors for growth of an amorphous boron nitride layer. For example, in at least one embodiment, the reaction gas may include triethylboron reacting with, e.g., NH₃ plasma to form the amorphous material layers 10 including amorphous boron nitride.

The substrate SUB may be a substrate for growing the amorphous material layers 10. The substrate SUB may be a substrate for forming amorphous boron nitride layers thereon. The substrate SUB may include, for example, at least one selected from a semiconductor material, an insulating material, and a metallically conductive material. The semiconductor material may include an elemental (e.g., Group IV) semiconductor and/or a compound semiconductor. The Group IV semiconductor may include, for example, Si, Ge, or Sn, but is not limited thereto. For example, the compound semiconductor may include a semiconductor material in which at least two elements selected from Si, Ge, C, Zn, Cd, Al, Ga, In, B, C, N, P, S, Se, As, Sb, and Te are combined with each other, a Group III-V compound semiconductor, and/or the like. The insulating material may include, for example, at least one of an oxide, a nitride, and/or a carbide of at least one selected from Si, Ni, Al, W, Ru, Co, Mn, Ti, Ta, Au, Hf, Zr, Zn, Y, Cr, Cu, Mo, and Gd; and derivatives thereof. The metallically conductive material may include a metal and/or a material including no bandgap within an operating range.

The amorphous material layers 10 may be grown on the substrate SUB by a deposition method using plasma. Examples of the deposition method using plasma include plasma enhanced chemical vapor deposition (PECVD), plasma enhanced atomic layer deposition (PEALD), inductively coupled plasma chemical vapor deposition (ICP-CVD), and/or the like. However, methods of growing the amorphous material layers 10 are not limited thereto, and various other methods may be used. For example, methods such as metal organic chemical vapor deposition (MOCVD), physical vapor deposition (PVD), and low pressure chemical vapor deposition (LPCVD) may be used to grow the amorphous material layers 10.

The amorphous material layers 10 may each have a first thickness. The first thickness may be within a range in which the amorphous material layers 10 may maintain an amorphous state. For example, the first thickness may be less than 50 nm. For example, the first thickness may be 10 nm or less. The first thickness may be 5 nm or less. The first thickness is greater than a second thickness (described later) of the intermediate layer 20. In at least some embodiments, when the thickness of a comparative layer is greater than the first thickness, a polycrystalline and/or a crystal state may be induced by an increase of the free energy in the amorphous material layer 10 above the crystal nucleation and/or propagation free energy barriers.

Therefore, when the first thickness of each of the amorphous material layers 10 is greater than a predetermined thickness as shown in FIG. 2, crystallization may occur and/or may dominantly occur in the amorphous material layers 10. For example, when the amorphous material layers 10 are boron nitride layers, crystallization may occur in the boron nitride layers when each of the boron nitride layers grow to a thickness of more than 10 nm. As described above, when the amorphous material layers 10 are crystallized or lose an amorphous state, the first dielectric constant of the amorphous material layers 10 may increase. In other words, when the thicknesses of the amorphous material layers 10 increases, the dielectric constant of the amorphous material layers 10 may rapidly increase. In this case, the amorphous material layers 10 having an increased dielectric constant may not be in an amorphous state.

Referring again to FIG. 1, according to at least one embodiment, the first thickness of the amorphous material layers 10 of the stacked structure 1 may be limited based on the consideration that the dielectric constant of the amorphous material layers 10 varies as the thickness of each of the amorphous material layers 10 varies, and the intermediate layer 20 may be disposed between the amorphous material layers 10.

The intermediate layer 20 may be disposed between the amorphous material layers 10 and be in contact with the amorphous material layers 10. For example, the intermediate layer 20 may be disposed directly on the first amorphous material layer 11, and the second amorphous material layer 12 may be disposed directly on the intermediate layer 20. Thus, the intermediate layer 20 may be in direct contact with an upper surface of the first amorphous material layer 11 and a lower surface of the second amorphous material layer 12.

The intermediate layer 20 disposed between the amorphous material layers 10 may prevent crystallization of the amorphous material layers 10 that may occur when the thicknesses of the amorphous material layers 10 increases. Thus, even when the overall thickness of the stacked structure 1 increases, the overall dielectric constant of the stacked structure 1 may be maintained within a predetermined range.

The intermediate layer 20 may have low interfacial reactivity with the amorphous material layers 10. For example, the intermediate layer 20 may be a two-dimensional material layer including a two-dimensional material. The two-dimensional material is a material having a two-dimensional crystal structure. The two-dimensional material may have a monolayer structure or a multilayer structure. Each layer that forms the two-dimensional material may have an atom-level thickness. For example, the intermediate layer 20 may have a monolayer structure. The intermediate layer 20 may have a second thickness that is less than the first thickness. For example, the second thickness may be 20% or less of the first thickness. The second thickness may be 10% or less of the first thickness. In at least some embodiment, the second thickness may be within a range of about 6% to about 20% of the first thickness and/or within a range of about 6% to about 10% of the first thickness. The second thickness may be 3 nm or less. The second thickness may be 1 nm or less. For example, the second thickness may range from about 0.3 nm to about 1 nm.

The two-dimensional material may include, for example, at least one selected from graphene, black phosphorous, and a transition metal dichalcogenide (TMD).

The TMD may include, for example, a transition metal selected from Mo, W, Nb, V, Ta, Ti, Zr, Hf, Tc, and Re, and a chalcogen element selected from S, Se, and Te. For example, the TMD may be expressed as MX2 in which M refers to a transition metal and X refers to a chalcogen element. For example, the M may be Mo, W, Nb, V, Ta, Ti, Zr, Hf, Tc, Re, or the like, and the X may be S, Se, Te, or the like. Thus, examples of the TMD may include MoS₂, MoSe₂, MoTe₂, WS₂, WSe₂, WTe₂, ZrS₂, ZrSe₂, HfS₂, HfSe₂, NbSe₂, ReSe₂, and/or the like. Alternatively, the TMD may not be expressed as MX2. The TMD may include MoS₂ that is a compound of a transition metal, M, and a chalcogen element, S. For example, the TMD may include CuS that is a compound of a transition metal, Cu, and a chalcogen element, S.

An operation of forming the intermediate layer 20 may be performed by a method that is commonly used for growing a two-dimensional material layer. For example, the intermediate layer 20 may be formed using a chemical vapor deposition (CVD) method. Examples of the CVD method may include rapid thermal chemical vapor deposition (RTCVD), inductively coupled plasma CVD (ICP-CVD), low pressure CVD (LPCVD), atmospheric pressure chemical vapor deposition (APCVD), metal-organic chemistry CVD (MOCVD), and/or plasma-enhanced CVD (PECVD), but are not limited thereto. In another example, the intermediate layer 20 may be formed through an atomic layer deposition (ALD) method. However, embodiments are not limited thereto, and the intermediate layer 20 may be formed by various deposition methods other than CVD and ALD.

The intermediate layer 20 may be formed directly on an amorphous material layer 10. Alternatively, the intermediate layer 20 may be formed on a layer other than the amorphous material layer 10 or the substrate SUB and may then be transferred to the amorphous material layer 10.

Another amorphous material layer 10 may be disposed on the intermediate layer 20. For example, the second amorphous material layer 12 may be disposed on the intermediate layer 20. Therefore, the intermediate layer 20 may be disposed between the amorphous material layers 10.

For example, the second amorphous material layer 12 may be grown on the intermediate layer 20. For example, an amorphous boron nitride layer may be grown on the intermediate layer 20. Even when the amorphous boron nitride layer is grown on the intermediate layer 20 rather than on the substrate SUB, the amorphous boron nitride layer may be in an amorphous state and may thus have a dielectric constant corresponding to the dielectric constant of an amorphous boron nitride layer grown on the substrate SUB. In other words, the dielectric constant of the second amorphous material layer 12 and the dielectric constant of the first amorphous material layer 11 may correspond to each other. For example, the dielectric constant of the second amorphous material layer 12 and the dielectric constant of the first amorphous material layer 11 may be the same or may be different from each other within an error range (e.g., 10% or less).

The second amorphous material layer 12 may be disposed on the intermediate layer 20 by the same method as the method of growing the first amorphous material layer 11 on the substrate SUB. For example, the second amorphous material layer 12 may be disposed on the intermediate layer 20 by a deposition method using plasma. Examples of the deposition method using plasma include PECVD, PEALD, ICP-CVD, and/or the like. However, the method of growing (disposing) the second amorphous material layer 12 is not limited thereto, and various other method may be used. Examples of the method of growing the second amorphous material layer 12 may include MOCVD, PVD, LPCVD, and/or the like.

Considering the overall dielectric constant of the stacked structure 1, the intermediate layer 20 may have a second dielectric constant within a predetermined range relative to the first dielectric constant. For example, the difference between the second dielectric constant and the first dielectric constant may be less than or equal to twice the first dielectric constant. For example, the difference between the second dielectric constant and the first dielectric constant may be less than or equal to the first dielectric constant. The second dielectric constant may be 7 or less. The second dielectric constant may be 5 or less. The second dielectric constant may be 3 or less.

The amorphous material layers 10 may correspond to each other in at least one of thickness and dielectric constant. For example, the thickness of the first amorphous material layer 11 and the thickness of the second amorphous material layer 12 may be the same, or the difference may be within 5% of the thickness of the first amorphous material layer 11. The first dielectric constant of the first amorphous material layer 11 and the first dielectric constant of the second amorphous material layer 12 may be the same, or the difference may be within 5% of the first dielectric constant of the first amorphous material layer 11.

The overall dielectric constant of the stacked structure 1 may be maintained at a level that is equal to or similar to the first dielectric constant of each of the amorphous material layers 10. For example, the difference between the overall dielectric constant and the first dielectric constant may be within 10% of the first dielectric constant. For example, when the first dielectric constant of each of the amorphous material layers 10 is 2.5 or less, the overall dielectric constant of the stacked structure 1 may be 2.6 or less. For example, when the first dielectric constant of each of the amorphous material layers 10 is 2.5 or less, the overall dielectric constant of the stacked structure 1 may be 2.5 or less.

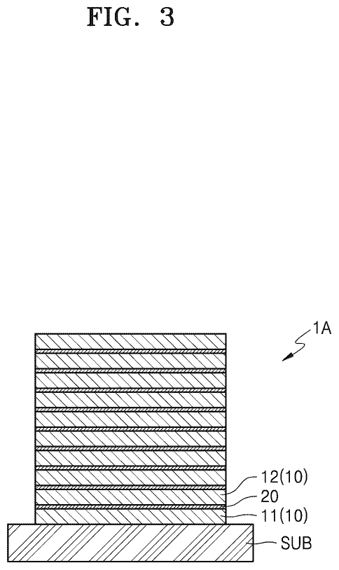

In the embodiments described above, the stacked structure 1 is described as having a three-layer structure, that is, two amorphous material layers 10 and one intermediate layer 20. However, embodiments are not limited thereto. For example, in at least one embodiment, a stacked structure 1A may have five or more amorphous material layers 10 and intermediate layers 20 between each of the amorphous material layers 10 as shown in FIG. 3. For example, the number of amorphous material layers 10 may be ten or more. For example, the number of amorphous material layers 10 may be twenty or more. However, the number of amorphous material layers 10 may be 10,000 or less. As such, wherein the number of amorphous material layers 10 is represented by an integer “n”, the number of intermediate layers 20 may be represented as “n-1”.

As described above, as the number of amorphous material layers 10 and the number of intermediate layers 20 increase, the overall thickness of the stacked structure 1A may increase. For example, the overall thickness of the stacked structure 1A may be 50 nm or more. For example, the overall thickness of the stacked structure 1A may be about 50 nm to about 1000 nm.

As described above, the intermediate layers 20, which are thinner than the amorphous material layers 10 and have the second dielectric constant similar to the dielectric constant of the amorphous material layers 10, are disposed between the amorphous material layers 10. Thus, although the thickness of the stacked structure 1 or 1A increases, the overall dielectric constant of the stacked structure 1 or 1A may be maintained at a low level. For example, the stacked structure 1 or 1A may have an overall dielectric constant of 2.5 or less. For example, the stacked structure 1 or 1A may have an overall thickness of 50 nm or more and an overall dielectric constant of 2.5 or less.

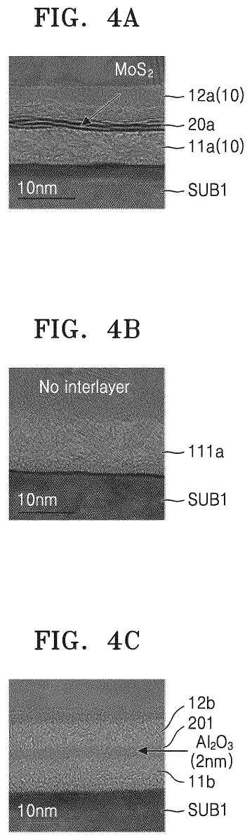

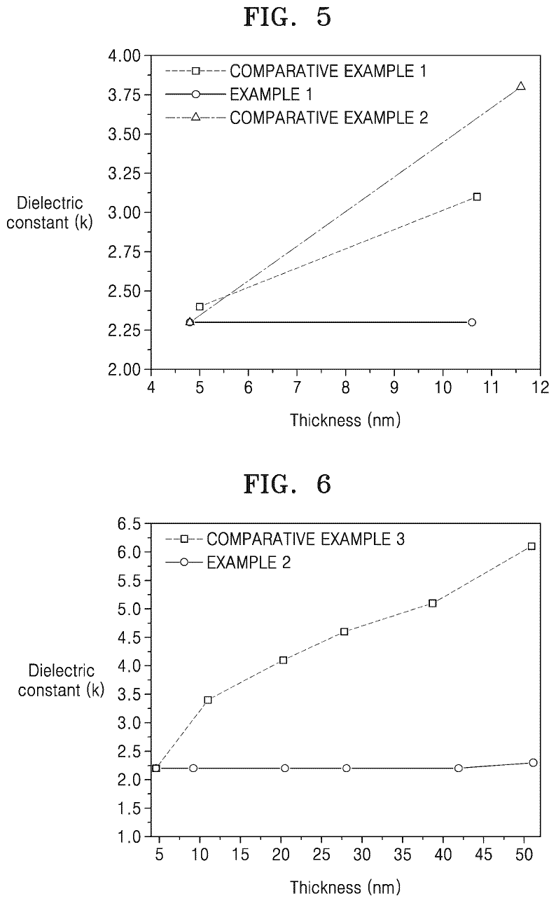

FIGS. 4A to 4C are images obtained using a scanning electron microscope (SEM) to show cross-sections of structures or stacked structures of Example 1 and Comparative Examples 1 and 2. FIG. 5 is a graph illustrating a relationship between a dielectric constant and a thickness in Example 1 and Comparative Examples 1 and 2.

Referring to FIG. 4A, in the stacked structure of Example 1, a 4.8-nm-thick amorphous boron nitride layer 11a, a 1-nm-thick molybdenum disulfide layer 20a, and a 4.8-nm-thick amorphous boron nitride layer 12a are sequentially stacked on a silicon substrate SUB1, and the overall thickness thereof is 10.6 nm. Referring to FIG. 4B, in the structure of Comparative Example 1, a boron nitride layer 111a having a thickness of about 10.7 nm is provided on a silicon substrate SUB without an intermediate layer. Referring to FIG. 4C, in the stacked structure of Comparative Example 2, a 4.8-nm-thick amorphous boron nitride layer 11b, a 2-nm-thick aluminum oxide layer 201, and a 4.8-nm-thick amorphous boron nitride layer 12b are sequentially stacked on a silicon substrate SUB1, and the overall thickness thereof is 11.6 nm.

Referring to FIG. 5, the structure of Comparative Example 1 has an overall dielectric constant of 3.0 to 3.1, and the stacked structure of Comparative Example 2 has an overall dielectric constant of 3.7 to 3.8. In addition, the stacked structure of Example 1 has an overall dielectric constant of about 2.2 to about 2.3.

Each boron nitride layer used in Example 1 and Comparative Examples 1 and 2 has a dielectric constant of 2.2 to 2.3 when having a thickness of 5 nm, and the dielectric constant of the boron nitride layer 111a of the structure of Comparative Example 1 increases to 3.0 to 3.1 because the thickness of the boron nitride layer 111a is two or more times the thickness of 5 nm. The reason for this is considered that as the thickness of the boron nitride layer 111a increases, crystallization occurring in the boron nitride layer 111a causes an increase in the dielectric constant of the boron nitride layer 111a.

However, the dielectric constant of the stacked structure of Example 1 remains at a level of 2.2 to 2.3 even though the overall thickness of the stacked structure of Example 1 is similar to the overall thickness of the structure of Comparative Example 1. This is considered because the molybdenum disulfide layer 20a having a small thickness and a low dielectric constant is disposed between the boron nitride layers 11a and 12a each having a small thickness in a range of 5 nm or less.

In addition, the dielectric constant of the stacked structure of Comparative Example 2 increases markedly even though the thicknesses of the boron nitride layers 11b and 12b are respectively equal to the thicknesses of the boron nitride layers 11a and 12a of Example 1. This is considered to be affected by the material and thickness of an intermediate layer (the aluminum oxide layer 201). In other words, it is considered that the aluminum oxide layer 201 used as an intermediate layer has a greater dielectric constant and a greater thickness than the molybdenum disulfide layer 20a used as an intermediate layer in Example 1, and thus, the overall dielectric constant of the stacked structure of Comparative Example 2 increases markedly.

FIG. 6 is a graph illustrating a relationship between a dielectric constant and a thickness of each of a stacked structure of Example 2 and a structure of Comparative Example 3. In the stacked structure of Example 2, boron nitride layers each having a first dielectric constant of 2.3 and a first thickness of 5 nm and molybdenum disulfide layers each having a thickness of 1 nm or less are alternately arranged on a silicon substrate SUB. In Example 2, as shown in FIG. 3, ten boron nitride layers and nine molybdenum disulfide layers are alternately arranged. In the structure of Comparative Example 3, a boron nitride layer without an intermediate layer is formed on a silicon substrate SUB up to a thickness of 50 nm.

Referring to FIG. 6, the overall dielectric constant of the structure of Comparative Example 3 increases up to 6.3. However, the overall dielectric constant of the stacked structure of Example 2 remains at a level of 2.3 or less. It is considered that the overall dielectric constant of the structure of Comparative Example 3 increases because an increase in the thickness of the boron nitride layer causes crystallization. However, the overall dielectric constant of the stacked structure of Example 2 remains at a low level. The reason for this is considered as follows. The thicknesses of each of the boron nitride layers does not increase even though the overall thickness of the stacked structure increases, thereby preventing crystallization. In addition, the molybdenum disulfide layers having a small thickness and a low dielectric constant are arranged between the boron nitride layers.

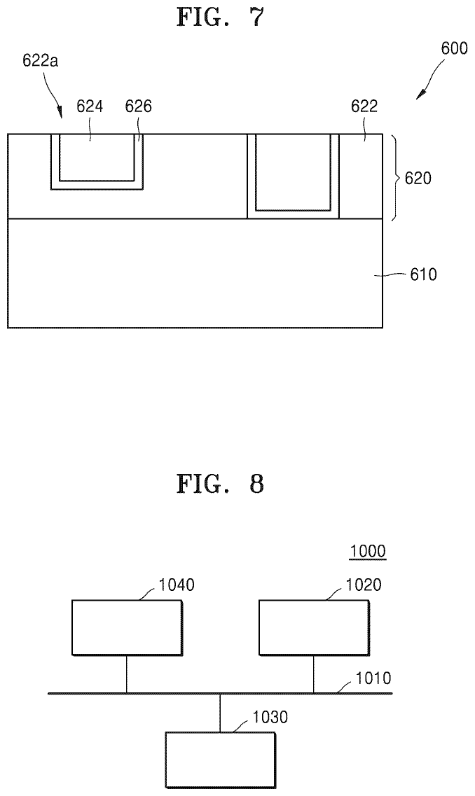

FIG. 7 is a cross-sectional view schematically illustrating a configuration of an electronic device 600 including a wiring structure 620 according to at least one embodiment. Referring to FIG. 7, the electronic device 600 may include a substrate 610 and the wiring structure 620 provided on the substrate 610. The wiring structure 620 may include a dielectric layer 622 and conductive wiring 624.

The substrate 610 may be a semiconductor substrate. For example, the substrate 610 may include a Group IV semiconductor material, a Group III-V compound semiconductor material, or a Group II-VI compound semiconductor material. For example, the substrate 610 may include at least one semiconductor material selected from Si, Ge, SiC, SiGe, SiGeC, Ge Alloy, GaAs, InAs, and InP. The semiconductor materials listed above are just examples, and the substrate 610 may include various other semiconductor materials. In addition, the substrate 610 may include a single layer or a plurality of layers formed by stacking different materials. For example, the substrate 610 may include a silicon-on-insulator (SOI) substrate or a silicon germanium-on-insulator (SGOI) substrate. In addition, the substrate 610 may include at least one semiconductor device (not shown). The at least one semiconductor device may include, for example, at least one selected from a transistor, a capacitor, a diode, and a resistor.

The dielectric layer 622 is formed on the substrate 610. The dielectric layer 622 may have a single or multilayer structure. In at least one embodiment, the dielectric layer 622 includes an insulator, such as an oxide and/or nitride of the semiconductor substrate. Alternatively, the dielectric layer 622 may include the stacked structure 1 or 1A of the embodiments described above. When the dielectric layer 622 includes the stacked structure 1 or 1A, the dielectric layer 622 may have a function of a diffusion barrier layer 626 (described later). In this case, the diffusion barrier layer 626 (described later) may be omitted.

At least one trench 622a having a predetermined depth may be formed in the dielectric layer 622. Here, the at least one trench 622a may be in contact with the substrate 610 or may be not in contact with the substrate 610. FIG. 7 illustrates an example in which two trenches 622a are formed in the dielectric layer 622 with one of the trenches 622a being not in contact with the substrate 610 and the other being in contact with the substrate 610.

The conductive wiring 624 is provided to fill the at least one trench 622a. In other words, the dielectric layer 622 may surround at least a portion of the conductive wiring 624.

The conductive wiring 624 may include a conductive material, such as a metal or metal alloy having high conductivity. For example, the conductive wiring 624 may include Cu, Ru, Al, Co, W, Mo, Ti, Ta, Ni, Pt, Cr, Rh, Ir, or an alloy thereof. However, the conductive wiring 624 is not limited thereto and may include various other metals.

The diffusion barrier layer 626 is provided on an inner wall of the at least one trench 622a. Here, the diffusion barrier layer 626 may be provided between the dielectric layer 622 and the conductive wiring 624 to cover the conductive wiring 624. For example, the diffusion barrier layer 626 may be provided on the inner wall of the at least one trench 622a to cover lateral and lower surfaces of the conductive wiring 624. An upper surface of the conductive wiring 624 may be exposed from the diffusion barrier layer 626. The diffusion barrier layer 626 may prevent diffusion of materials forming the conductive wiring 624. In addition, the diffusion barrier layer 626 may additionally function as an adhesive layer between the dielectric layer 622 and the conductive wiring 624. In at least one embodiment, the diffusion barrier layer 626 may include the stacked structure 1 or 1A of the embodiments described above.

FIG. 8 is a schematic of an electronic device according to at least one embodiment. Referring to FIG. 8, the electronic device 1000 includes one or more electronic device components, including a processor (e.g., processing circuitry) 1020 and a memory 1030 that are communicatively coupled together via a bus 1010.

The processing circuitry 1020, may be included in, may include, and/or may be implemented by one or more instances of processing circuitry such as hardware including logic circuits, a hardware/software combination such as a processor executing software; or a combination thereof. For example, the processing circuitry 1020 may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. In some example embodiments, the memory 1030 may include a non-transitory computer readable storage device, for example a solid state drive (SSD), storing a program of instructions, and the processing circuitry 1020 may be configured to execute the program of instructions to implement the functionality of the electronic device 1000.

In some example embodiments, the electronic device 1000 may include one or more additional components 1040, coupled to bus 1010, which may include, for example, a power supply, a light sensor, a light-emitting device, any combination thereof, and/or the like. In some example embodiments, one or more of the processing circuitry 1020, memory 1030, one or more additional components 1040, and/or the connecting structures therebetween may include any of the stacked structure and/or electronic devices according to any of the example embodiments described with reference to, e.g., FIGS. 1, 3, 7, and/or the like.

As described above, according to the one or more of the above embodiments, the stacked structure, the electronic device, and the method of fabricating the stacked structure guarantee a low dielectric constant even when the thickness of the stacked structure is greater than or equal to a predetermined value.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A stacked structure comprising:
a plurality of amorphous material layers each having a first thickness and a first dielectric constant of 2.5 or less; and
an intermediate layer between each of the plurality of amorphous material layers, the intermediate layer having a second dielectric constant and a second thickness less than the first thickness,
wherein a difference between the first dielectric constant and the second dielectric constant is less than or equal to twice the first dielectric constant, and
wherein an overall dielectric constant of the stacked structure is 2.5 or less.

2. The stacked structure of claim 1, wherein each of the plurality of amorphous material layers comprises an amorphous material including at least one of carbon (C), silicon (Si), boron (B), nitrogen (N), or oxygen (O).

3. The stacked structure of claim 2, wherein each of the plurality of amorphous material layers comprises amorphous boron nitride, and
the first dielectric constant is 2.3 or less.

4. The stacked structure of claim 1, wherein the intermediate layer comprises a two-dimensional thin-film layer comprising a two-dimensional material.

5. The stacked structure of claim 4, wherein the two-dimensional material comprises at least one of a transition metal dichalcogenide, graphene, black phosphorus, or two-dimensional hexagonal boron nitride (h-BN).

6. The stacked structure of claim 1, wherein the second thickness is 1 nm (nanometer) or less.

7. The stacked structure of claim 1, wherein the second thickness is 20% or less of the first thickness.

8. The stacked structure of claim 1, wherein a difference between the overall dielectric constant and the first dielectric constant is within 10% of the first dielectric constant.

9. The stacked structure of claim 1, wherein a number of the plurality of amorphous material layers is five or more.

10. The stacked structure of claim 1, wherein an overall thickness of the stacked structure is 50 nm (nanometers) or more.

11. An electronic device comprising;
a substrate; and
a wiring structure on the substrate,
wherein the wiring structure comprises
conductive wiring, and
a dielectric layer surrounding at least a portion of the conductive wiring,
wherein the dielectric layer comprises the stacked structure of claim 1.

12. A method of fabricating a stacked structure, the method comprising:
forming a first amorphous material layer on a substrate such that the first amorphous material layer has a first thickness and a first dielectric constant of 2.5 or less;
forming an intermediate layer on the first amorphous material layer such that the intermediate layer has a second dielectric constant and a second thickness less than the first thickness; and
forming a second amorphous material layer on the intermediate layer such that the second amorphous material layer has a third thickness greater than the second thickness and a third dielectric constant of 2.5 or less,
wherein a difference between the first dielectric constant and the second dielectric constant is less than or equal to twice the first dielectric constant and a difference between the third dielectric constant and the second dielectric constant is less than or equal to twice the third dielectric constant, and
wherein an overall dielectric constant of the stacked structure is 2.5 or less.

13. The method of claim 12, wherein the first and second amorphous material layers are formed such that each of the first and second amorphous material layers is formed of an amorphous material including at least one of carbon (C), silicon (Si), boron (B), nitrogen (N), or oxygen (O).

14. The method of claim 12, wherein the first and second amorphous material layers are formed such that each of the first and second amorphous material layers comprise amorphous boron nitride.

15. The method of claim 12, wherein the intermediate layer is formed such that the intermediate layer comprises a two-dimensional thin-film layer comprising a two-dimensional material.

16. The method of claim 15, wherein the two-dimensional material comprises at least one of a transition metal dichalcogenide, graphene, black phosphorus, or two-dimensional hexagonal boron nitride (h-BN).

17. The method of claim 12, wherein the intermediate layer is formed such that the second thickness of the intermediate layer is 1 nm (nanometer) or less.

18. The method of claim 12, wherein the intermediate layer is formed such that the second thickness of the intermediate layer is 20% or less of the first thickness of each of the first and second amorphous material layers.

19. The method of claim 12, wherein the forming of the intermediate layer and the forming of the second amorphous material layer are alternately repeated such that the stacked structure includes a plurality of the intermediate layer between a plurality of the second amorphous material layer.

20. The method of claim 19, wherein a total number of the first and second amorphous material layers is five or more, and
an overall thickness of the stacked structure is 50 nm (nanometers) or more.
